(19) United States
(12) Patent Application Publication
(10) Pub. No.: US 2026/0173663 A1
(43) Pub. Date: Jun. 18, 2026

(54) DISPLAY PANEL AND DISPLAY DEVICE

(71) Applicants: Hefei Visionox Technology Co., Ltd., Hefei (CN); Visionox Technology Inc., Kunshan (CN)

(72) Inventors: Zhiwei ZHOU, Hefei (CN); Yingyu FENG, Kunshan (CN); Jinfang ZHANG, Hefei (CN); Lu ZHANG, Hefei (CN)

(73) Assignees: Hefei Visionox Technology Co., Ltd., Hefei (CN); Visionox Technology Inc., Kunshan (CN)

(21) Appl. No.: 19/408,275

(22) Filed: Dec. 3, 2025

(30) Foreign Application Priority Data
Dec. 13, 2024 (CN) 202411849483.2

(51) Int. Cl. H10K 59/122; H10K 59/35

(52) U.S. Cl. CPC H10K 59/122; H10K 59/353

(57) ABSTRACT

The present application provides a display panel and a display device. The display panel includes: a substrate; a plurality of first pixel drive units and a plurality of first via holes; a plurality of first pixel openings, an edge of the first pixel opening including a first straight portion, a second straight portion and a recessed portion, and a plurality of first light-emitting devices, the first light-emitting device being at least partially located in the first pixel opening and connected to the first pixel drive unit through the first via hole. The recessed portion has a second orthographic projection on the substrate, and an area of a first orthographic projection on a side of a first extension line close to the second orthographic projection is less than an area of the first orthographic projection on a side of the first extension line away from the second orthographic projection.

### CROSS-REFERENCE TO RELATED APPLICATIONS

The present application claims priority to the Chinese Patent Application No. 202411849483.2, filed on Dec. 13, 2024, and the entire contents of the aforementioned application are hereby incorporated by reference in its entirety.

### FIELD

The present application relates to the field of display, and specifically, relates to a display panel and a display device.

### BACKGROUND

During the preparation of conventional display panels, light-emitting pixel patterning is usually implemented by means of a fine metal mask (FMM). FMM technology is mature and has rich experience in mass production. However, the FMM technology also has problems such as limited accuracy, high development costs, and long development cycle. Fine metal mask-free technology eliminates the limitations of conventional OLED processes on display size, resolution, and other screen performances, and has the advantages of high performance, full-size coverage and agile delivery. Reference can be made to relevant contents of the fine metal mask-free technology recited in Chinese patents CN 118251982 A, CN 116648095 A, CN 117062489 A, CN 118742138 A, CN 118678783 A, CN 118660598 A, CN 118675450 A, CN 118824188 A and CN 118781966 A.

### SUMMARY

In view of this, one or more embodiments of the present application provide a display panel and a display device.

One or more embodiments of the present application provide a display panel, including:
a substrate;
an array circuit layer located on a side of the substrate and including a plurality of pixel drive units and a plurality of via holes, the plurality of pixel drive units including a plurality of first pixel drive units, and the via holes including a plurality of first via holes;
a pixel defining layer located on a side of the array circuit layer having the plurality of via holes, the pixel defining layer including a plurality of pixel openings, the plurality of pixel openings including a plurality of first pixel openings, an edge of the first pixel opening including a first straight portion, a second straight portion and a recessed portion, the first straight portion and the second straight portion being parallel and extending in a first direction, the recessed portion being connected to the first straight portion and extending in a second direction away from an extension line of the first straight portion and toward the second straight portion, and the first direction intersecting with the second direction; and
a plurality of light-emitting devices, including a plurality of first light-emitting devices, the first light-emitting device being at least partially located in a corresponding one of the plurality of first pixel openings and connected to a corresponding one of the plurality of first pixel drive units through a corresponding one of the plurality of first via holes,
where the first via hole has a first orthographic projection on the substrate, a straight line where an orthographic projection of the first straight portion on the substrate lies is a first extension line, the recessed portion has a second orthographic projection on the substrate, and an area of the first orthographic projection on a side of the first extension line close to the second orthographic projection is less than an area of the first orthographic projection on a side of the first extension line away from the second orthographic projection.

One or more embodiments of the present application provide a display panel, including:
a substrate;
an array circuit layer located on a side of the substrate and including a plurality of pixel drive units and a plurality of via holes, the plurality of pixel drive units including a plurality of first pixel drive units, and the via holes including a plurality of first via holes;
a pixel defining layer located on a side of the array circuit layer having the plurality of via holes, the pixel defining layer including a plurality of pixel openings, the plurality of pixel openings including a plurality of first pixel openings, an edge of the first pixel opening including a first straight portion, a second straight portion and a recessed portion, the first straight portion and the second straight portion being parallel and extending in a first direction, the recessed portion being connected to the first straight portion and extending in a second direction away from an extension line of the first straight portion and toward the second straight portion, and the first direction intersecting with the second direction;
an isolation structure enclosing a plurality of isolation openings, the plurality of isolation openings including a plurality of first isolation openings, the first isolation opening being in communication with a corresponding one of the plurality of first pixel openings; and
a plurality of light-emitting devices, including a plurality of first light-emitting devices, the first light-emitting device being at least partially located in a corresponding one of the plurality of first isolation openings and connected to a corresponding one of the plurality of first pixel drive units through a corresponding one of the plurality of first via holes,
where the first via hole has a first orthographic projection on the substrate, a straight line where an orthographic projection of the first straight portion on the substrate lies is a first extension line, the recessed portion has a second orthographic projection on the substrate, and an area of the first orthographic projection on a side of the first extension line close to the second orthographic projection is less than an area of the first orthographic projection on a side of the first extension line away from the second orthographic projection.

One or more embodiments of the present application provide a display device, including the display panel described above.

In the display panel according to the embodiments of the present application, the edge of the first pixel opening includes the first straight portion, the second straight portion and the recessed portion, and the corresponding positional relationship between the recessed portion and the first via hole facilitates an increase in the area of the orthographic projection of the first pixel opening on the substrate, and thus facilitates an improvement in the aperture ratio of pixels in the display panel. Moreover, the first via hole does not interfere with the light-emitting devices in the remaining pixel openings, and the display panel has an excellent display effect.

### BRIEF DESCRIPTION OF THE DRAWINGS

FIG. 1 is a structural schematic top view of a display panel according to one or more embodiments of the present application.

FIG. 2 is a structural schematic top view of a display panel according to one or more embodiments of the present application.

FIG. 3 is a structural schematic cross-sectional view of a display panel according to one or more embodiments of the present application.

FIG. 4 is a structural schematic top view of a display panel according to one or more embodiments of the present application.

FIG. 5 is a structural schematic view of an arrangement of a first lower electrode, a second lower electrode and a third lower electrode according to one or more embodiments of the present application.

FIG. 6 is a structural schematic view of the arrangement of the first lower electrode, the second lower electrode and the third lower electrode according to one or more embodiments of the present application.

FIG. 7 is a structural schematic enlarged view of a first pixel opening according to one or more embodiments of the present application.

FIG. 8 is a structural schematic cross-sectional view of a display panel according to one or more embodiments of the present application.

FIG. 9 is a structural schematic cross-sectional view of an isolation structure according to one or more embodiments of the present application.

FIG. 10 is a structural schematic cross-sectional view of an isolation structure according to one or more embodiments of the present application.

FIG. 11 is a structural schematic cross-sectional view of an isolation structure according to still one or more embodiments of the present application.

FIG. 12 is a structural schematic cross-sectional view of a display panel according to one or more embodiments of the present application.

FIG. 13 is a schematic flowchart of a method for preparing a display panel according to one or more embodiments of the present application.

FIG. 14 is a schematic flowchart of a method for preparing a display panel according to one or more embodiments of the present application.

### DETAILED DESCRIPTION OF THE EMBODIMENTS

Terms such as “first” and “second” in the description, claims, and above drawings of the present application are used to distinguish between similar objects and are not necessarily used to describe a particular order or sequence. It is to be understood that data used in this manner is interchangeable in appropriate cases and the embodiments of the present application described herein can also be implemented in an order not illustrated or described herein. In addition, terms “comprising”, “including”, and any variation thereof are intended to encompass a non-exclusive inclusion. For example, a process, method, system, product, or device that includes a series of steps or units not only includes the expressly listed steps or units, but may also include other steps or units that are not expressly listed or are inherent to such a process, method, product, or device.

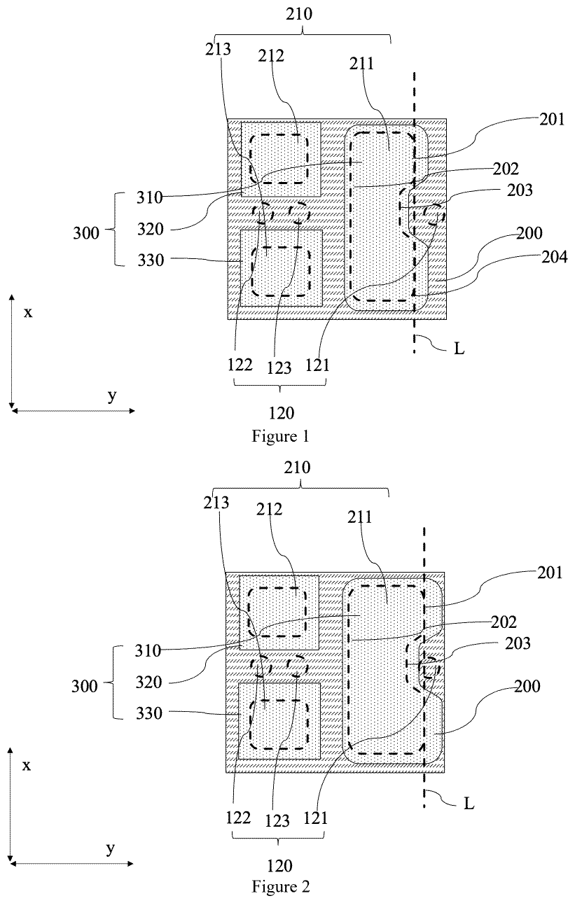

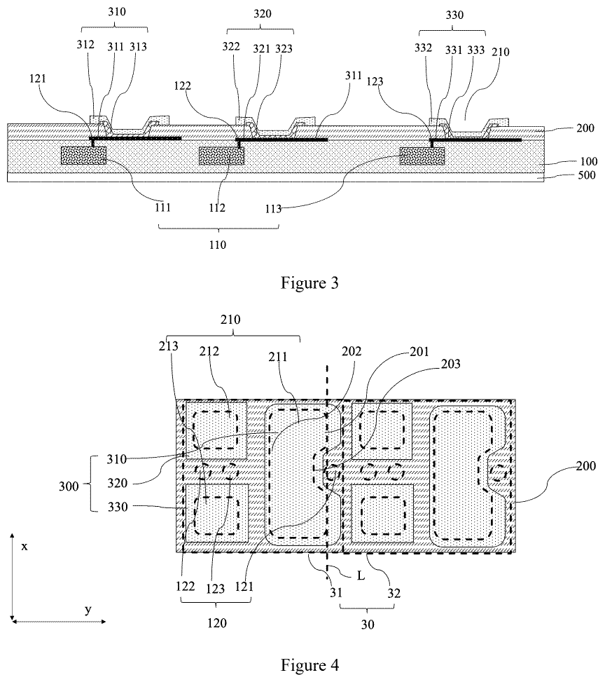

One or more embodiments of the present application provide a display panel. Referring to the structural schematic top views of the display panel shown in FIGS. 1 and 2 and the structural schematic cross-sectional view shown in FIG. 3, the display panel includes: a substrate 500; an array circuit layer 100 located on one side of the substrate 500, and including a plurality of pixel drive units 110 and a plurality of via holes 120, the plurality of pixel drive units 110 including a plurality of first pixel drive units 111, and the plurality of via holes 120 including a plurality of first via holes 121; a pixel defining layer 200 located on a side of the array circuit layer 100 having the plurality of via holes 120, the pixel defining layer 200 including a plurality of pixel openings 210, the plurality of pixel openings 210 including a plurality of first pixel openings 211, an edge of the first pixel opening 211 including a first straight portion 201, a second straight portion 202 and a recessed portion 203, the first straight portion 201 and the second straight portion 202 being parallel and extending in a first direction x, the recessed portion 203 being connected to the first straight portion 201 and extending in a second direction y away from an extension line of the first straight portion 201 and toward the second straight portion 202, and the first direction x intersecting with the second direction y; and a plurality of light-emitting devices 300, the plurality of light-emitting devices 300 including a plurality of first light-emitting devices 310, the first light-emitting device 310 being at least partially located in the first pixel opening 211 and connected to the first pixel drive unit 111 through the first via hole 121, for example, the first light-emitting device 310 being at least partially located in a corresponding one of the plurality of first pixel openings 211 and connected to a corresponding one of the plurality of first pixel drive units 111 through a corresponding one of the plurality of first via holes 121. The first via hole 121 has a first orthographic projection on the substrate 500, a straight line where an orthographic projection of the first straight portion 201 on the substrate 500 lies is a first extension line L, the recessed portion 203 has a second orthographic projection on the substrate 500, and an area of the first orthographic projection on a side of the first extension line L close to the second orthographic projection is less than an area of the first orthographic projection on a side of the first extension line L away from the second orthographic projection.

In the display panel according to the embodiment of the present application, the edge of the first pixel opening 211 includes the first straight portion 201, the second straight portion 202 and the recessed portion 203, the positional corresponding relationship between the recessed portion 203 and the first via hole 121, i.e., the area of the first orthographic projection on the side of the first extension line L close to the second orthographic projection being less than the area of the first orthographic projection on the side of the first extension line L away from the second orthographic projection, facilitates an increase in the area of the orthographic projection of the first pixel opening 211 on the substrate 500, and thus facilitates an improvement in the aperture ratio of pixels in the display panel. Moreover, the first via hole 121 does not interfere with the light-emitting devices 300 in the remaining pixel openings, and the display panel has an excellent display effect.

It should be understood that where the area of the first orthographic projection on the side of the first extension line L close to the second orthographic projection is less than the area of the first orthographic projection on the side of the first extension line L away from the second orthographic projection, and the position of the first via hole 121 is not changed, the opening area of the first pixel opening 211 can be increased by means of the movement of the first straight portion 201 toward the first via hole 121 without changing.

By way of example, referring to FIG. 1, the first extension line L is located outside the first orthographic projection. In this case, the area of the first orthographic projection on the side of the first extension line L close to the second orthographic projection is 0. By way of example, referring to FIG. 2, the first extension line L passes through the first orthographic projection. In this way, the opening area of the first pixel opening 211 can be effectively increased.

In at least an embodiment, the first extension line L passes through the first orthographic projection, the area of the first orthographic projection on the side of the first extension line L close to the second orthographic projection accounts for 10%-40%, which, for example, may be 10%, 20%, 30%, or 40%, of a total area of the first orthographic projection. In this way, an increase in the area of the orthographic projection of the first pixel opening 211 on the substrate 500 is further facilitated, and the width of the pixel defining layer 200 enclosing the first pixel openings 211 is appropriate. Moreover, the light-emitting device 300 in the first pixel opening 211 is hardly electrically connected to the light-emitting device 300 in the adjacent pixel opening 210, and the yield of the display panel is improved.

In at least an embodiment, referring to FIGS. 1 and 2, the plurality of light-emitting devices 300 further includes second light-emitting devices 320 and third light-emitting devices 330, and the display panel includes a plurality of pixels 30 arranged in an array. The pixel 30 includes the first light-emitting device 310, the second light-emitting device 320 and the third light-emitting device 330. In the same pixel 30, the first light-emitting device 310 and the second light-emitting device 320 are arranged in the second direction y, the first light-emitting device 310 and the third light-emitting device 330 are arranged in the second direction y, the second light-emitting device 320 and the third light-emitting device 330 are arranged in the first direction x, and the second light-emitting device 320 and the third light-emitting device 330 are located on the same side of the first light-emitting device 310.

By way of example, the first direction x and the second direction y are perpendicular to each other. In an embodiment, the plurality of pixel openings 210 further includes a plurality of second pixel openings 212 and a plurality of third pixel openings 213. The second light-emitting device 320 is at least partially located in the second pixel opening 212(for example a corresponding one of the plurality of second pixel openings 212), and the third light-emitting device 330 is at least partially located in the third pixel opening 213(for example a corresponding one of the plurality of third pixel openings 213).

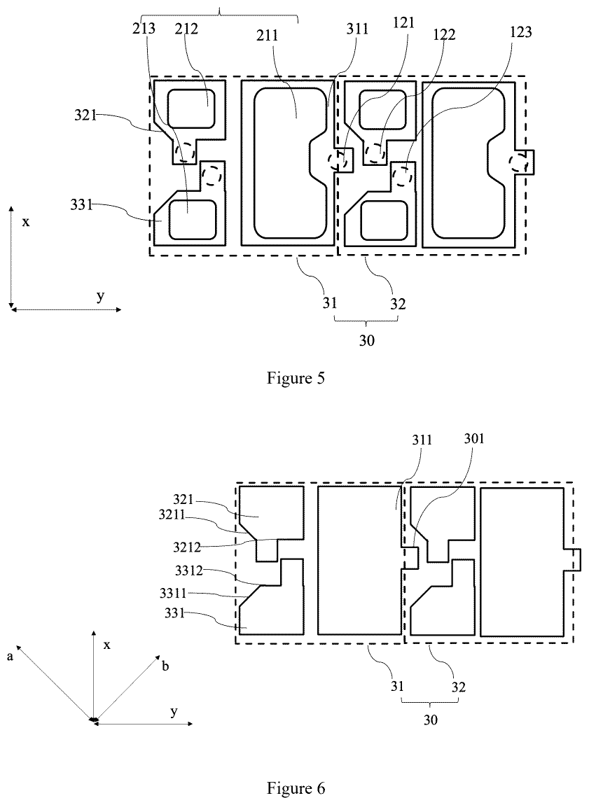

In at least an embodiment, referring to the structural schematic top views of the display panel shown in FIGS. 3 and 4, and the structural schematic view of an arrangement of first lower electrodes, second lower electrodes and third lower electrodes of two adjacent pixels shown in FIG. 5, the plurality of pixel drive units 110 further includes a plurality of second pixel drive units 112 and a plurality of third pixel drive units 113, and the plurality of via holes 120 further includes a plurality of second via holes 122 and a plurality of third via holes 123. The first light-emitting device 310 includes a first lower electrode 311, a partial structure of the first lower electrode 311 extends to the first via hole 121 (for example the corresponding first via hole 121) and is connected to the first pixel drive unit 111 (for example the corresponding first pixel drive unit 111), the second light-emitting device 320 includes a second lower electrode 321, a partial structure of the second lower electrode 321 extends to the second via hole 122 (for example a corresponding one of the plurality of second via holes 122) and is connected to the second pixel drive unit 112 (for example a corresponding one of the plurality of second pixel drive units 112), the third light-emitting device 330 includes a third lower electrode 331, and a partial structure of the third lower electrode 331 extends to the third via hole 123 (for example a corresponding one of the plurality of third via holes 123) and is connected to the third pixel drive unit 113 (for example a corresponding one of the plurality of third pixel drive units 113). Part of the first lower electrode 311 is located between the second lower electrode 321 and the third lower electrode 331. In this way, the part of the first via hole 121, which moves to the first lower electrode 311 in the direction away from the first pixel opening 211, is located between the second lower electrode 321 and the third lower electrode 331, facilitating an increase in the opening area of the first pixel opening 211 and thus facilitating an improvement in the aperture ratio of the display panel.

By way of example, FIGS. 1, 2 and 4 are structural schematic top views, the first pixel opening 211, the second pixel opening 212 and the third pixel opening 213 cannot be shown directly and are indicated by dashed lines, which cannot be construed as limiting the present application.

By way of example, the plurality of pixels 30 includes first pixels 31 and second pixels 32 adjacent to each other. The first lower electrode 311 of the first pixel 31 is located between the second lower electrode 321 and the third lower electrode 331 of the second pixel 32. In this way, the arrangement of the pixels 30 is reasonable, facilitates an increase in the opening area of each first pixel opening 211, and thus facilitates an improvement in the aperture ratio of the display panel.

By way of example, the first light-emitting device 310 is a blue light-emitting device, one of the second light-emitting device 320 and the third light-emitting device 330 is a red light-emitting device, and the other of the second light-emitting device 320 and the third light-emitting device 330 is a green light-emitting device. For example, the first light-emitting device 310 is the blue light-emitting device, the second light-emitting device 320 is the red light-emitting device, and the third light-emitting device 330 is the green light-emitting device.

In at least an embodiment, referring to the structural schematic view of the arrangement of the first lower electrodes, the second lower electrodes and the third lower electrodes shown in FIG. 6, the first lower electrode 311 includes a protruding segment 301, the second lower electrode 321 includes a first edge 3211 and a second edge 3212 close to the third lower electrode 331, and the third lower electrode 331 includes a third edge 3311 and a fourth edge 3312 close to the second lower electrode 321; and the protruding segment 301 of the first pixel 31 extends toward the second lower electrode 321 or the third lower electrode 331 of the second pixel 32, the first edge 3211 of the second lower electrode 321 of the second pixel 32 is close to the protruding segment 301 of the first lower electrode 311 of the first pixel 31, and the third edge 3311 of the third lower electrode 331 of the second pixel 32 is close to the protruding segment 301 of the first lower electrode 311 of the first pixel 31. In this way, the configuration of the protruding segment 301 of the first lower electrode 311 facilitates the movement of the first via hole 121 in the direction away from the first pixel opening 211 and thus facilitates an increase in the opening area of the first pixel opening 211.

By way of example, the protruding segment 301 of the first pixel 31 extends toward the second lower electrode 321 and the third lower electrode 331 of the second pixel 32.

In at least an embodiment, a shortest distance between an orthographic projection of the second pixel opening 212 on the substrate 500 and an orthographic projection of the first edge 3211 on the substrate 500 is less than a shortest distance between the orthographic projection of the second pixel opening 212 on the substrate 500 and an orthographic projection of the second edge 3212 on the substrate 500; and a shortest distance between an orthographic projection of the third pixel opening 213 on the substrate 500 and an orthographic projection of the third edge 3311 on the substrate 500 is less than a shortest distance between the orthographic projection of the third pixel opening 213 on the substrate 500 and an orthographic projection of the fourth edge 3312 on the substrate 500. By way of example, the orthographic projection of the second lower electrode 321 of the second pixel 32 on the substrate 500 is a first rectangle, a first chamfer is formed at a vertex of the first rectangle close to the first pixel opening 211 and the third pixel opening 213, and the first edge 3211 may be an edge line of the first chamfer; and the orthographic projection of the second lower electrode 321 of the third pixel 33 on the substrate 500 is a second rectangle, a second chamfer is formed at a vertex of the second rectangle close to the first pixel opening 211 and the second pixel opening 212, and the third edge 3311 may be an edge line of the second chamfer. In this way, the configuration of the first edge 3211 and the third edge 3311 facilitates the configuration of the protruding segment 301 and thus facilitates an improvement in the aperture ratio of the display panel.

In at least an embodiment, referring to FIG. 6, the first edge 3211 extends in a third direction a, the second edge 3212 extends in the second direction y, the third edge 3311 extends in a fourth direction b, the fourth edge 3312 extends in the second direction y, the third direction a intersects with the first direction x, the second direction y and the fourth direction b, and the fourth direction b intersects with the first direction x and the second direction y.

In at least an embodiment, referring to FIG. 1, the edge of the first pixel opening 211 further includes a third straight portion 204. The recessed portion 203 is connected between the first straight portion 201 and the third straight portion 204. A straight line where the third straight portion 204 lies is located between a straight line where the first straight portion 201 lies and a straight line where the second straight portion 202 lies, or the straight line where the third straight portion 204 lies and the straight line where the first straight portion 201 lies are the same straight line. In this way, the movement of the first straight portion 201 and the third straight portion 204 toward the first via hole 121 further facilitates an increase in the opening area of the first pixel opening 211.

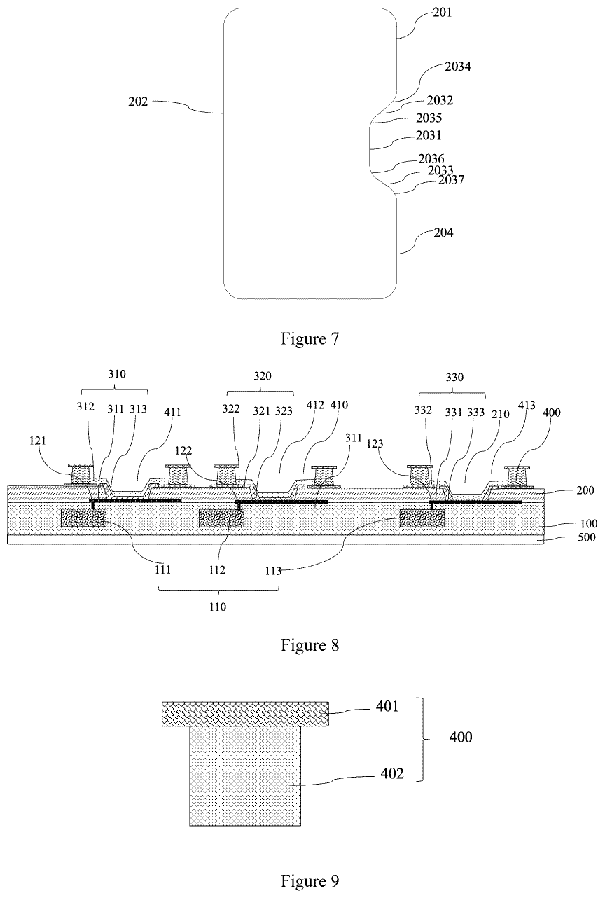

In at least an embodiment, referring to the structural schematic top view of the first pixel opening shown in FIG. 7, the recessed portion 203 includes a fourth straight portion 2031, a fifth straight portion 2032, a sixth straight portion 2033, a first curved portion 2034, a second curved portion 2035, a third curved portion 2036 and a fourth curved portion 2037. The fourth curved portion 2037 is close to the second straight portion 202 and extends in the first direction x, the fifth straight portion 2032 extends in a direction intersecting with both the first direction x and the second direction y, and the sixth straight portion 2033 extends in a direction intersecting with both the first direction x and the second direction y; and the first curved portion 2034 is connected between the first straight portion 201 and the fifth straight portion 2032, the second curved portion 2035 is connected between the fifth straight portion 2032 and the fourth straight portion 2031, the third curved portion 2036 is connected between the fourth straight portion 2031 and the sixth straight portion 2033, and the fourth curved portion 2037 is connected between the sixth straight portion 2033 and the third straight portion 204. In this way, the shape of the recessed portion 203 is easy to manufacture and facilitates an increase in the opening area of the first pixel opening 211.

In at least an embodiment, an included angle between the first straight portion 201 and the fifth straight portion 2032 is greater than 90 degrees, an included angle between the fifth straight portion 2032 and the fourth straight portion 2031 is greater than 90 degrees, an included angle between the fourth straight portion 2031 and the sixth straight portion 2033 is greater than 90 degrees, and an included angle between the sixth straight portion 2033 and the third straight portion 204 is greater than 90 degrees. This facilitates the formation of the recessed portion 203, facilitates an increase in the opening area of the first pixel opening 211, and facilitates the fabrication of the first pixel opening 211.

In at least an embodiment, the first light-emitting device 310 includes a first upper electrode 312 on a side of the first lower electrode 311 away from the substrate 500, the second light-emitting device 320 includes a second upper electrode 322 on a side of the second lower electrode 321 away from the substrate 500, and the third light-emitting device 330 includes a third upper electrode 332 on a side of the third lower electrode 331 away from the substrate 500. In an embodiment, referring to the structural schematic cross-sectional view of the display panel shown in FIG. 8, the display panel further includes: an isolation structure 400, the isolation structure 400 enclosing a plurality of isolation openings 410. The plurality of isolation openings 410 includes first isolation openings 411, second isolation openings 412 and third isolation openings 413. The first isolation opening 411 is in communication with the first pixel opening 211 (for example the corresponding first pixel opening 211), the second isolation opening 412 is in communication with the second pixel opening 212 (for example the corresponding second pixel opening 212), the third isolation opening 413 is in communication with the third pixel opening 213 (for example the corresponding third pixel opening 213), and the first upper electrode 312, the second upper electrode 322 and the third upper electrode 332 are in contact with the isolation structure 400. This facilitates the implementation of a front cathode structure.

By way of example, the first light-emitting device 310 further includes a first light-emitting functional layer 313 located between the first lower electrode 311 and the first upper electrode 312. The second light-emitting device 320 further includes a second light-emitting functional layer 323 located between the second lower electrode 321 and the second upper electrode 322. The third light-emitting device 330 further includes a third light-emitting functional layer 333 located between the third lower electrode 331 and the third upper electrode 332.

By way of example, the first light-emitting device 310 is illustrated as an example, one of the first lower electrode 311 and the first upper electrode 312 is an anode, and the other of the first lower electrode 311 and the first upper electrode 312 is a cathode. By way of example, the first light-emitting functional layer 313 includes an emitting layer (EML), and may further include at least one of a hole inject layer (HIL), a hole transport layer (HTL) and an electron-blocking layer (EBL) located between the anode and the emitting layer (EML), and at least one of an electron inject layer (EIL), an electron transport layer (ETL) and a hole-blocking layer (HBL) located between the cathode and the emitting layer (EML).

By way of example, the isolation structure 400 is located on a side of the pixel defining layer 200 away from the substrate 500; the orthographic projection of the first pixel opening 211 on the substrate 500 is located within a range of an orthographic projection of the first isolation opening 411 on the substrate 500; the orthographic projection of the second pixel opening 212 on the substrate 500 is located within a range of an orthographic projection of the second isolation opening 412 on the substrate 500; and the orthographic projection of the third pixel opening 213 on the substrate 500 is located within a range of an orthographic projection of the third isolation opening 413 on the substrate 500.

In at least an embodiment, one part of the first lower electrode 311 is located between the pixel defining layer 200 and the array circuit layer 100, another part of the first lower electrode is exposed from the first pixel opening 211, one part of the second lower electrode 321 is located between the pixel defining layer 200 and the array circuit layer 100, another part of the second lower electrode is exposed from the second pixel opening 212, one part of the third lower electrode 331 is located between the pixel defining layer 200 and the array circuit layer 100, and another part of the third lower electrode is exposed from the third pixel opening 213.

By way of example, the first lower electrode 311 is connected to the first pixel drive unit 111 through the first via hole 121; the second lower electrode 321 is connected to the second pixel drive unit 112 through the second via hole 122; and the third lower electrode 331 is connected to the third pixel drive unit 113 through the third via hole 123.

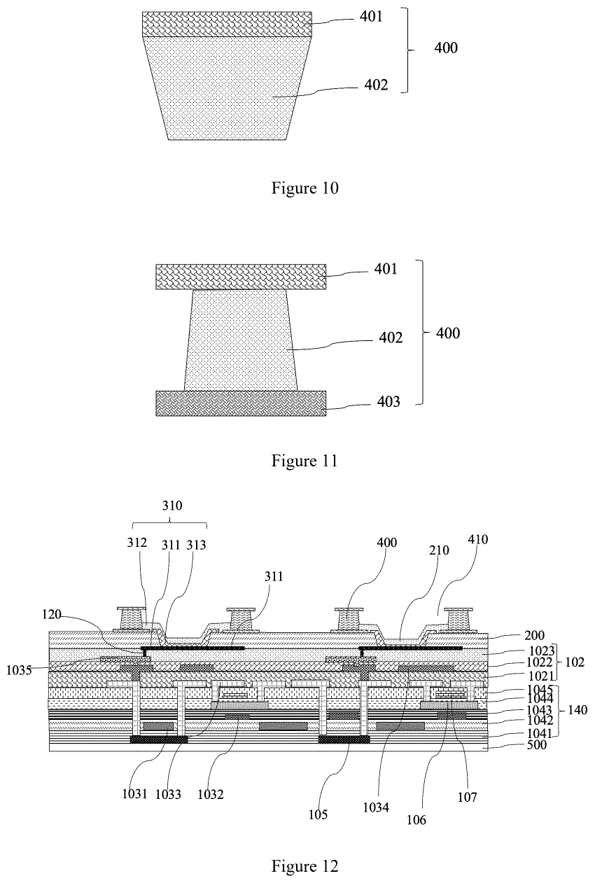

In at least an embodiment, referring to the structural schematic views of the isolation structure shown in FIGS. 9 and 10, the isolation structure 400 includes a first portion 401 and a second portion 402 that are stacked. The first portion 401 is located on a side of the second portion 402 away from the substrate 500, and an orthographic projection of the second portion 402 on the substrate 500 is located within an orthographic projection of the first portion 401 on the substrate 500. By way of example, the second portion 402 may be designed as a separate film layer, that is, there is no physical interface inside the second portion 402, and the parts are made of the same material. For example, the material of the second portion 402 is aluminum. In one embodiment, the second portion 402 may be designed to include at least two stacked film layers. For example, the second portion 402 is formed by stacking two conductive film layers, the materials of the two conductive film layers may be molybdenum and aluminum respectively, and the conductive film layer made of molybdenum is located between the array circuit layer 100 and the conductive film layer made of aluminum. By way of example, the second portion 402 includes a conductive sub-part, or the second portion 402 is of a conductive structure itself. The second portion 402 overlaps and is connected to the upper electrode of each of the light-emitting devices 300 whereas the upper electrodes of the adjacent light-emitting devices 300 are electrically connected to each other, thereby achieving a full-surface cathode. The first portion 401 may be made of an organic material, an inorganic material or a metallic material. When the first portion 401 is made of a metallic material, the second portion 402 may be made of titanium. In this case, the cross-section of the isolation structure 400 is in a T shape or an inverted trapezoidal shape.

In at least an embodiment, referring to the structural schematic view of the isolation structure shown in FIG. 11, the isolation structure 400 further includes a third portion 403 located on a side of the second portion 402 close to the substrate 500, and the orthographic projection of the second portion 402 on the substrate 500 is located within a range of an orthographic projection of the third portion 403 on the substrate 500. The upper electrode of each of the light-emitting devices may effectively overlap and be connected to the third portion 403 or the second portion 402, thereby achieving a full-surface cathode.

By way of example, the upper electrode of each of the light-emitting devices may effectively overlap and be connected to the third portion 403 and the second portion 402, thereby achieving a full-surface cathode.

In at least an embodiment, in a direction parallel to a plane where the substrate 500 is located, a minimum width of the pixel defining layer 200 between adjacent pixel openings 210 is 6-20 μm, for example, may be 6 μm, 8 μm, 10 μm, 12 μm, 14 μm, 16 μm, 18 μm, or 20 μm. This facilitates an improvement in the aperture ratio of the pixels of the display panel, and the pixel defining layer 200 can effectively cover the via holes 120 and the lower electrode of each of the light-emitting devices.

By way of example, the above structures of the isolation structure 400 can effectively isolate the light-emitting functional layer from the upper electrode. By way of example, when the light-emitting functional layer is prepared by means of evaporation, the isolation structure 400 can effectively isolate the evaporated light-emitting functional material layer to obtain the light-emitting functional layer located in the isolation opening 410, and the light-emitting functional layer having higher accuracy can be obtained without using a mask, and the yield of the display panel is improved, and production costs are reduced.

In at least an embodiment, referring to the structural schematic cross-sectional view of the display panel shown in FIG. 12, the array circuit layer 100 further includes a planarization layer 102. The planarization layer 102 has the via holes 120.

In at least an embodiment, referring to FIG. 12, the array circuit layer 100 further includes a metal layer 103 and an insulation layer 104. The metal layer 103 includes a first metal layer 1031, a second metal layer 1032 and a third metal layer 1033 that are sequentially stacked. The first metal layer 1031 is located on a side of the second metal layer 1032 close to a base substrate 101, and the insulation layer 104 is located between every two adjacent metal layers of the first metal layer 1031, the second metal layer 1032 and the third metal layer 1033.

By way of example, the pixel drive unit 110 includes a pixel drive circuit, the pixel drive circuit including a transistor and a storage capacitor. The transistor includes a semiconductor, a gate, a source and a drain. The storage capacitor includes a first plate and a second plate. As an example, the gate and the first plate may be located in the first metal layer 1031, the second plate may be located in the second metal layer 1032, and the source and the drain may be located in the third metal layer 1033.

In at least one embodiment, referring to FIG. 10, the display panel includes: a base substrate 101; a metal active layer 105 located on one side of the base substrate 101; a first gate insulation layer 1041 located on a side of the metal active layer 105 away from the base substrate 101; a first metal layer 1031 located on a side of the first gate insulation layer 1041 away from the base substrate 101; a capacitive insulation layer 1042 located on a side of the first metal layer 1031 away from the base substrate 101; a second metal layer 1032 located on a side of the capacitive insulation layer 1042 away from the base substrate 101; a buffer layer 1043 located on a side of the second metal layer 1032 away from the base substrate 101; an oxide active layer 106 located on a side of the buffer layer 1043 away from the base substrate 101; a second gate insulation layer 1044 located on a side of the oxide active layer 106 away from the base substrate 101; an oxide gate layer 107 located on a side of the second gate insulation layer 1044 away from the base substrate 101; an interlayer dielectric layer 1045 located on a side of the oxide gate layer 107 away from the base substrate 101; a third metal layer 1033 located on a side of the interlayer dielectric layer 1045 away from the base substrate 101; a third planarization layer 1021 located on a side of the third metal layer 1033 away from the base substrate 101; a fourth metal layer 1034 located on a side of the third planarization layer 1021 away from the base substrate 101; a second planarization layer 1022 located on a side of the fourth metal layer 1034 away from the base substrate 101; a fifth metal layer 1035 located on a side of the second planarization layer 1022 away from the base substrate 101; a first planarization layer 1023 located on a side of the fifth metal layer 1035 away from the base substrate 101, the first planarization layer 1023 having via holes 120; first lower electrodes 311 located on a side of the first planarization layer 1023 away from the base substrate 101, the first lower electrode 311 extending into the via hole 120 and being electrically connected to the fifth metal layer 1035; a pixel defining layer 200 located on a side of the first lower electrodes 311 away from the base substrate 101, the pixel defining layer 200 having a plurality of pixel openings 210, and part of the first lower electrode 311 being exposed to the pixel opening 210; an isolation structure 400 located on a side of the pixel defining layer 200 away from the base substrate 101, the isolation structure 400 having a plurality of isolation openings 410, the isolation opening 410 being arranged corresponding to the pixel opening 210, and an orthographic projection of the isolation opening 410 on the base substrate 101 covering an orthographic projection of the pixel opening 210 on the base substrate 101; a first light-emitting functional layer 313, part of the first light-emitting functional layer 313 being located in the pixel opening 210, the remaining part of the first light-emitting functional layer 313 extending outwardly from the pixel opening 210 into the isolation opening 410 and extending to a side of the pixel defining layer 200 away from the first lower electrode 311; and first upper electrodes 312 located on a side of the first light-emitting functional layer 313 away from the base substrate 101, part of the first upper electrode 312 being located in the pixel opening 210, and the remaining part of the first upper electrode 312 extending outwardly from the first opening 210 into the isolation opening 410 and overlapping and being connected to the isolation structure 400.

By way of example, the first gate insulation layer 1041, the capacitive insulation layer 1042, the buffer layer 1043, the second gate insulation layer 1044 and the interlayer dielectric layer 1045 form the insulation layer 140. The first metal layer 1031, the second metal layer 1032 and the third electrode layer 1033 constitute the metal layer 103. The first planarization layer 1023, the second planarization layer 1022 and the third planarization layer 1021 form the planarization layer 102.

By way of example, the lower electrode of each of the light-emitting devices is electrically connected to the fifth metal layer 1035, thereby achieving electrical connection with the pixel drive circuit.

By way of example, the material of the oxide active layer 106 includes, but is not limited to, indium gallium zinc oxide (abbreviated as IGZO), and the material of the oxide gate layer 107 includes, but is not limited to, nano cesium tungsten oxide (GATO).

In some embodiments, the substrate may be a glass-based base substrate. In an embodiment, the substrate may include an organic resin material such as epoxy, triazine, silicone, or polyimide. For example, the substrate may be an FR4 type printed circuit board (PCB), or may be a deformable flexible PCB. In an embodiment, the substrate may include a ceramic material such as silicon nitride, aluminum nitride, or aluminum trioxide, or include metal or a metal compound. For example, the substrate may be a metal core PCB (MCPCB) or a metal copper clad laminate (MCCL).

One or more embodiments of the present application provide a display panel, including: a substrate 500; an array circuit layer 100 located on a side of the substrate 500, and including a plurality of pixel drive units 110 and a plurality of via holes 120, the plurality of pixel drive units 110 including a plurality of first pixel drive units 111, and the plurality of via holes 120 including a plurality of first via holes 121; a pixel defining layer 200 located on a side of the array circuit layer 100 having the plurality of via holes 120, the pixel defining layer 200 including a plurality of pixel openings 210, the plurality of pixel openings 210 including a plurality of first pixel openings 211, an edge of the first pixel opening 211 including a first straight portion 201, a second straight portion 202 and a recessed portion 203, the first straight portion 201 and the second straight portion 202 being parallel and extending in a first direction x, the recessed portion 203 being connected to the first straight portion 201 and extending in a second direction y away from an extension line of the first straight portion 201 and toward the second straight portion 202, and the first direction x intersecting with the second direction y; an isolation structure 400 enclosing a plurality of isolation openings 410, the plurality of isolation openings 410 including a plurality of first isolation openings 411, the first isolation opening 411 being in communication with a corresponding one of the plurality of first pixel openings 211; and a plurality of light-emitting devices 300, the plurality of light-emitting devices 300 including a plurality of first light-emitting devices 310, the first light-emitting device 310 being at least partially located in the first isolation opening 410 and connected to the first pixel drive unit 111 through the first via hole 121, for example, the first light-emitting device 310 being at least partially located in a corresponding one of the plurality of first isolation openings 410 and connected to a corresponding one of the plurality of first pixel drive units 111 through a corresponding one of the plurality of first via holes 121. The first via hole 121 has a first orthographic projection on the substrate 500, a straight line where an orthographic projection of the first straight portion 201 on the substrate 500 lies is a first extension line L, the recessed portion 203 has a second orthographic projection on the substrate 500, and an area of the first orthographic projection on a side of the first extension line L close to the second orthographic projection is less than an area of the first orthographic projection on a side of the first extension line L away from the second orthographic projection.

In at least an embodiment, the first extension line L is located outside the first orthographic projection. In this case, the area of the first orthographic projection on the side of the first extension line L close to the second orthographic projection is 0. In another embodiment, the first extension line L passes through the first orthographic projection. In this way, the opening area of the first pixel opening 211 can be effectively increased.

In at least an embodiment, the plurality of light-emitting devices 300 further includes a plurality of second light-emitting devices 320 and a plurality of third light-emitting devices 330, and the display panel includes a plurality of pixels 30 arranged in an array. The pixel 30 includes the first light-emitting device 310, the second light-emitting device 320 and the third light-emitting device 330. In the same pixel 30, the first light-emitting device 310 and the second light-emitting device 320 are arranged in the second direction y, the first light-emitting device 310 and the third light-emitting device 330 are arranged in the second direction y, the second light-emitting device 320 and the third light-emitting device 330 are arranged in the first direction x, and the second light-emitting device 320 and the third light-emitting device 330 are located on the same side of the first light-emitting device 310.

By way of example, the first direction x and the second direction y are perpendicular to each other.

In at least an embodiment, the plurality of pixel openings 210 further includes a plurality of second pixel openings 212 and a plurality of third pixel openings 213. The second light-emitting device 320 is at least partially located in the second pixel opening 212 (for example a corresponding one of the plurality of second pixel openings 212), and the third light-emitting device 330 is at least partially located in the third pixel opening 213 (for example a corresponding one of the plurality of third pixel openings 213).

In at least an embodiment, the plurality of pixel drive units 110 further includes a plurality of second pixel drive units 112 and a plurality of third pixel drive units 113, and the plurality of via holes 120 further includes a plurality of second via holes 122 and a plurality of third via holes 123. The first light-emitting device 310 includes a first lower electrode 311, a partial structure of the first lower electrode 311 extends to the first via hole 121 (for example the corresponding first via hole 121) and is connected to the first pixel drive unit 111 (for example the corresponding first pixel drive unit 111), the second light-emitting device 320 includes a second lower electrode 321, a partial structure of the second lower electrode 321 extends to the second via hole 122 and is connected to the second pixel drive unit 112 (for example a corresponding one of the plurality of second pixel drive units 112), the third light-emitting device 330 includes a third lower electrode 331, and a partial structure of the third lower electrode 331 extends to the third via hole 123 and is connected to the third pixel drive unit 113 (for example a corresponding one of the plurality of third via holes 123). Part of the first lower electrode 311 is located between the second lower electrode 321 and the third lower electrode 331. In this way, the part of the first via hole 121, which moves to the first lower electrode 311 in the direction away from the first pixel opening 211, is located between the second lower electrode 321 and the third lower electrode 331, facilitating an increase in the opening area of the first pixel opening 211 and thus facilitating an improvement in the aperture ratio of the display panel.

By way of example, the plurality of pixels 30 includes first pixels 31 and second pixels 32 adjacent to each other. The first lower electrode 311 of the first pixel 31 is located between the second lower electrode 321 and the third lower electrode 331 of the second pixel 32. In this way, the arrangement of the pixels 30 is reasonable, facilitates an increase in the opening area of each first pixel opening 211, and thus facilitates an improvement in the aperture ratio of the display panel.

By way of example, the first light-emitting device 310 is a blue light-emitting device, one of the second light-emitting device 320 and the third light-emitting device 330 is a red light-emitting device, and the other of the second light-emitting device 320 and the third light-emitting device 330 is a green light-emitting device. For example, the first light-emitting device 310 is the blue light-emitting device, the second light-emitting device 320 is the red light-emitting device, and the third light-emitting device 330 is the green light-emitting device.

In at least an embodiment, the first light-emitting device 310 includes a first upper electrode 312 on a side of the first lower electrode 311 away from the substrate 500, the second light-emitting device 320 includes a second upper electrode 322 on a side of the second lower electrode 321 away from the substrate 500, and the third light-emitting device 330 includes a third upper electrode 332 on a side of the third lower electrode 331 away from the substrate 500; and the first upper electrode 312, the second upper electrode 322 and the third upper electrode 332 are in contact with the isolation structure 400. This facilitates the implementation of a front cathode structure.

It should be understood that the first light-emitting device 310 further includes a first light-emitting functional layer 313 located between the first lower electrode 311 and the first upper electrode 312. The second light-emitting device 320 further includes a second light-emitting functional layer 323 located between the second lower electrode 321 and the second upper electrode 322. The third light-emitting device 330 further includes a third light-emitting functional layer 333 located between the third lower electrode 331 and the third upper electrode 332.

By way of example, the first light-emitting device 310 is illustrated as an example, one of the first lower electrode 311 and the first upper electrode 312 is an anode, and the other of the first lower electrode 311 and the first upper electrode 312 is a cathode. By way of example, the first light-emitting functional layer 313 includes an emitting layer (EML), and may further include at least one of a hole inject layer (HIL), a hole transport layer (HTL) and an electron-blocking layer (EBL) located between the anode and the emitting layer (EML), and at least one of an electron inject layer (EIL), an electron transport layer (ETL) and a hole-blocking layer (HBL) located between the cathode and the emitting layer (EML).

In at least an embodiment, referring to FIG. 1, the edge of the first pixel opening 211 further includes a third straight portion 204. The recessed portion 203 is connected between the first straight portion 201 and the third straight portion 204. A straight line where the third straight portion 204 lies is located between a straight line where the first straight portion 201 lies and a straight line where the second straight portion 202 lies, or the straight line where the third straight portion 204 lies and the straight line where the first straight portion 201 lies are the same straight line. In this way, the movement of the first straight portion 201 and the third straight portion 204 toward the first via hole 121 further facilitates an increase in the opening area of the first pixel opening 211.

In at least an embodiment, the recessed portion 203 includes a fourth straight portion 2031, a fifth straight portion 2032, a sixth straight portion 2033, a first curved portion 2034, a second curved portion 2035, a third curved portion 2036 and a fourth curved portion 2037. The fourth curved portion 2037 is close to the second straight portion 202 and extends in the first direction x, the fifth straight portion 2032 extends in a direction intersecting with both the first direction x and the second direction y, and the sixth straight portion 2033 extends in a direction intersecting with both the first direction x and the second direction y; and the first curved portion 2034 is connected between the first straight portion 201 and the fifth straight portion 2032, the second curved portion 2035 is connected between the fifth straight portion 2032 and the fourth curved portion 2037, the third curved portion 2036 is connected between the fourth straight portion 2031 and the sixth straight portion 2033, and the fourth curved portion 2037 is connected between the sixth straight portion 2033 and the third straight portion 204. In this way, the shape of the recessed portion 203 is easy to manufacture and facilitates an increase in the opening area of the first pixel opening 211.

In at least an embodiment, an included angle between the first straight portion 201 and the fifth straight portion 2032 is greater than 90 degrees, an included angle between the fifth straight portion 2032 and the fourth straight portion 2031 is greater than 90 degrees, an included angle between the fourth straight portion 2031 and the sixth straight portion 2033 is greater than 90 degrees, and an included angle between the sixth straight portion 2033 and the third straight portion 204 is greater than 90 degrees. This facilitates the formation of the recessed portion 203, facilitates an increase in the opening area of the first pixel opening 211, and facilitates the fabrication of the first pixel opening 211.

It should be noted that the display panel in this embodiment may be combined entirely or partially with the display panel described above, and will not be described in more detail herein.

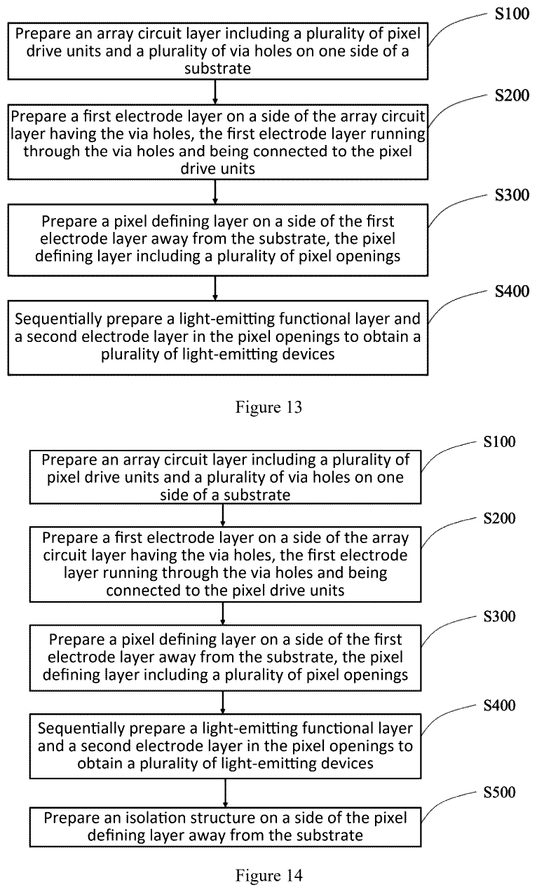

One or more embodiments of the present application provide a method for preparing a display panel. Referring to the schematic flowchart of the method for preparing a display panel shown in FIG. 13, the method for preparing a display panel includes the following steps.

In step S100, an array circuit layer including a plurality of pixel drive units and a plurality of via holes is prepared on one side of a substrate.

The plurality of pixel drive units includes first pixel drive units, and the plurality of via holes includes first via holes.

In step S200, a first electrode layer is prepared on a side of the array circuit layer having the via holes, the first electrode layer running through the via holes and being connected to the pixel drive units.

It should be noted that the first electrode layer may include the first lower electrode layer, the second lower electrode layer and the third lower electrode layer mentioned above.

In step S300, a pixel defining layer is prepared on a side of the first electrode layer away from the substrate, the pixel defining layer including a plurality of pixel openings.

It should be noted that the plurality of pixel openings include first pixel openings, and the first pixel opening is consistent with the foregoing description, and will not be described in more detail herein.

It should be noted that the pixel defining layer is consistent with the foregoing description, and will not be described in more detail herein.

By way of example, the step of preparing a pixel defining layer on a side of the first electrode layer away from the substrate includes: preparing a pixel defining material layer on the side of the first electrode layer away from the substrate, and patterning the pixel defining material layer to obtain the pixel defining layer. The pixel defining material layer may be patterned according to the actual shape of the pixel opening during the patterning process.

In step S400, a light-emitting functional layer and a second electrode layer are sequentially prepared in the pixel openings to obtain a plurality of light-emitting devices.

It should be noted that the second electrode layer may include the first upper electrodes, the second upper electrodes and the third upper electrodes mentioned above.

It should be noted that the light-emitting functional layer, the second electrode layer and the light-emitting devices are consistent with the foregoing description, and will not be described in more detail herein.

In at least an embodiment, referring to the schematic flowchart of a method for preparing a display panel shown in FIG. 14, the method for preparing a display panel further includes the following step.

In step S500, an isolation structure is prepared on a side of the pixel defining layer away from the substrate.

In at least an embodiment, the step of preparing an isolation structure on a side of the pixel defining layer away from the substrate includes: sequentially preparing a second isolation material layer and a first isolation material layer on the side of the pixel defining layer away from the substrate; and patterning the first isolation material layer and the second isolation material layer to obtain a plurality of isolation openings and stacked first and second portions, the first portion being located on a side of the second portion away from the substrate, and an orthographic projection of the second portion on the substrate being located within an orthographic projection of the first portion on the substrate. By way of example, the isolation structure may be made of stacked materials having different etching rates, that is, the etching rates of the first isolation material layer and the second isolation material layer are different. For example, the material of the first isolation material layer is titanium, the material of the second isolation material layer is aluminum, and the etching rate of the second isolation material layer is greater than the etching rate of the first isolation material layer. A method for preparing the isolation structure includes the following steps: sequentially preparing the second isolation material layer and the first isolation material layer, which are stacked, on the side of the first electrode layer away from the substrate, and etching, in the same etching environment, more material of the second isolation material layer to form the second portion of the isolation structure, and fewer material of the first isolation material layer to form the first portion of the isolation structure.

In at least an embodiment, the step of preparing an isolation structure on a side of the pixel defining layer away from the substrate includes: sequentially preparing a third isolation material layer, a second isolation material layer and a first isolation material layer on the side of the pixel defining layer away from the substrate; and patterning the first isolation material layer, the second isolation material layer and the third isolation material layer to obtain a plurality of isolation openings and first, second and third portions stacked sequentially, the first portion being located on a side of the second portion away from the substrate, an orthographic projection of the second portion on the substrate being located within a range of an orthographic projection of the first portion on the substrate, and the orthographic projection of the second portion on the substrate being located within a range of an orthographic projection of the third portion on the substrate. By way of example, the isolation structure may be made of stacked materials having different etching rates, that is, the etching rates of the third isolation material layer, the second isolation material layer and the first isolation material layer are different. For example, the material of the first isolation material layer and the third isolation material layer is titanium, the material of the second isolation material layer is aluminum, and the etching rate of the second isolation material layer is greater than the etching rates of the first isolation material layer and the third isolation material layer. A method for preparing the isolation structure includes the following steps: sequentially preparing the third isolation material layer, the second isolation material layer and the first isolation material layer, which are stacked, on the side of the first electrode layer away from the substrate, and etching, in the same etching environment, more material of the second isolation material layer to form the second portion of the isolation structure, and fewer material of the first isolation material layer and the third isolation material layer to form the first portion and the third portion of the isolation structure.

One or more embodiments of the present application provide a display device, including the display panel described above, or the display panel prepared by the preparation method described above.

In addition to the display panel described above, the display device may further include structures with which a conventional display device should be equipped, such as a touch panel and a driver chip, which will not be described in more detail herein.

The above description has been given for purposes of illustration and description. Moreover, this description is not intended to limit the embodiments of the present application to the form disclosed herein.

1. A display panel, comprising:
a substrate;
an array circuit layer located on a side of the substrate and comprising a plurality of pixel drive units and a plurality of via holes, the plurality of pixel drive units comprising a plurality of first pixel drive units, and the plurality of via holes comprising a plurality of first via holes;
a pixel defining layer located on a side of the array circuit layer having the plurality of via holes, the pixel defining layer comprising a plurality of pixel openings, the plurality of pixel openings comprising a plurality of first pixel openings, an edge of the first pixel opening comprising a first straight portion, a second straight portion and a recessed portion, the first straight portion and the second straight portion being parallel and extending in a first direction, the recessed portion being connected to the first straight portion and extending in a second direction away from an extension line of the first straight portion and toward the second straight portion, and the first direction intersecting with the second direction; and
a plurality of light-emitting devices comprising a plurality of first light-emitting devices, the first light-emitting device being at least partially located in a corresponding one of the plurality of first pixel openings and connected to a corresponding one of the plurality of first pixel drive units through a corresponding one of the plurality of first via holes,
wherein the first via hole has a first orthographic projection on the substrate, a straight line where an orthographic projection of the first straight portion on the substrate lies is a first extension line, the recessed portion has a second orthographic projection on the substrate, and an area of the first orthographic projection on a side of the first extension line close to the second orthographic projection is less than an area of the first orthographic projection on a side of the first extension line away from the second orthographic projection.

2. The display panel according to claim 1, wherein the first extension line is located outside the first orthographic projection, or the first extension line passes through the first orthographic projection.

3. The display panel according to claim 2, wherein the first extension line passes through the first orthographic projection, and the area of the first orthographic projection on the side of the first extension line close to the second orthographic projection accounts for 10%-40% of a total area of the first orthographic projection.

4. The display panel according to claim 1, wherein the plurality of light-emitting devices further comprises a plurality of second light-emitting devices and a plurality of third light-emitting devices, and the display panel comprises a plurality of pixels arranged in an array, the pixel comprising the first light-emitting device, the second light-emitting device and the third light-emitting device, wherein
in the same pixel, the first light-emitting device and the second light-emitting device are arranged in the second direction, the first light-emitting device and the third light-emitting device are arranged in the second direction, the second light-emitting device and the third light-emitting device are arranged in the first direction, and the second light-emitting device and the third light-emitting device are located on the same side of the first light-emitting device.

5. The display panel according to claim 4, wherein the plurality of pixel drive units further comprises a plurality of second pixel drive units and a plurality of third pixel drive units, and the plurality of via holes further comprise a plurality of second via holes and a plurality of third via holes, wherein
the first light-emitting device comprises a first lower electrode, a partial structure of the first lower electrode extending to the corresponding first via hole and being connected to the corresponding first pixel drive unit, the second light-emitting device comprises a second lower electrode, a partial structure of the second lower electrode extending to a corresponding one of the plurality of second via holes and being connected to a corresponding one of the plurality of second pixel drive units, and the third light-emitting device comprises a third lower electrode, a partial structure of the third lower electrode extending to a corresponding one of the plurality of third via holes and being connected to a corresponding one of the plurality of third pixel drive units; and
part of the first lower electrode is located between the second lower electrode and the third lower electrode.

6. The display panel according to claim 5, wherein the plurality of pixels comprise first pixels and second pixels adjacent to each other, part of the first lower electrode of the first pixel being located between the second lower electrode and the third lower electrode of the second pixel; and
the first light-emitting device is a blue light-emitting device, one of the second light-emitting device and the third light-emitting device is a red light-emitting device, and the other of the second light-emitting device and the third light-emitting device is a green light-emitting device.

7. The display panel according to claim 6, wherein the plurality of pixel openings further comprises a plurality of second pixel openings and a plurality of third pixel openings, the second light-emitting device being at least partially located in a corresponding one of the plurality of second pixel openings, and the third light-emitting device being at least partially located in a corresponding one of the plurality of third pixel openings, wherein
the first lower electrode comprises a protruding segment, the second lower electrode comprises a first edge and a second edge close to the third lower electrode, and the third lower electrode comprises a third edge and a fourth edge close to the second lower electrode; and
the protruding segment of the first pixel extends toward the second lower electrode and the third lower electrode of the second pixel, the first edge of the second lower electrode of the second pixel is close to the protruding segment of the first lower electrode of the first pixel, and the third edge of the third lower electrode of the second pixel is close to the protruding segment of the first lower electrode of the first pixel.

8. The display panel according to claim 7, wherein a shortest distance between an orthographic projection of the second pixel opening on the substrate and an orthographic projection of the first edge on the substrate is less than a shortest distance between the orthographic projection of the second pixel opening on the substrate and an orthographic projection of the second edge on the substrate;
a shortest distance between an orthographic projection of the third pixel opening on the substrate and an orthographic projection of the third edge on the substrate is less than a shortest distance between the orthographic projection of the third pixel opening on the substrate and an orthographic projection of the fourth edge on the substrate; and
the first edge extends in a third direction, the second edge extends in the second direction, the third edge extends in a fourth direction, the fourth edge extends in the second direction, the third direction intersects with the first direction, the second direction and the fourth direction, and the fourth direction intersects with the first direction and the second direction.

9. The display panel according to claim 7, wherein the first light-emitting device comprises a first upper electrode on a side of the first lower electrode away from the substrate, the second light-emitting device comprises a second upper electrode on a side of the second lower electrode away from the substrate, and the third light-emitting device comprises a third upper electrode on a side of the third lower electrode away from the substrate; the display panel further comprises:
an isolation structure located on a side of the pixel defining layer away from the substrate, the isolation structure enclosing a plurality of isolation openings, the plurality of isolation openings comprising a plurality of first isolation openings, a plurality of second isolation openings and a plurality of third isolation openings, the first isolation opening being in communication with the corresponding first pixel opening, the second isolation opening being in communication with the corresponding second pixel opening, the third isolation opening being in communication with the corresponding third pixel opening, and the first upper electrode, the second upper electrode and the third upper electrode being in contact with the isolation structure;
one part of the first lower electrode is located between the pixel defining layer and the array circuit layer, another part of the first lower electrode is exposed from the first pixel opening, one part of the second lower electrode is located between the pixel defining layer and the array circuit layer, another part of the second lower electrode is exposed from the second pixel opening, one part of the third lower electrode is located between the pixel defining layer and the array circuit layer, and another part of the third lower electrode is exposed from the third pixel opening; the isolation structure comprises a first portion and a second portion that are stacked, the first portion being arranged on a side of the second portion away from the substrate, and an orthographic projection of a side of the second portion close to the first portion on the substrate being located within an orthographic projection of the first portion on the substrate; and
the isolation structure further comprises a third portion located on a side of the second portion close to the substrate, an orthographic projection of a side of the second portion close to the third portion on the substrate being located within a range of an orthographic projection of the third portion on the substrate.

10. The display panel according to claim 1, wherein the edge of the first pixel opening further comprises a third straight portion, the recessed portion being connected between the first straight portion and the third straight portion, wherein
a straight line where the third straight portion lies is located between a straight line where the first straight portion lies and a straight line where the second straight portion lies, or the straight line where the third straight portion lies and the straight line where the first straight portion lies are the same straight line.

11. The display panel according to claim 10, wherein the recessed portion comprises a fourth straight portion, a fifth straight portion, a sixth straight portion, a first curved portion, a second curved portion, a third curved portion and a fourth curved portion, wherein
the fourth straight portion is close to the second straight portion and extends in the first direction, the fifth straight portion extends in a direction intersecting with both the first direction and the second direction, and the sixth straight portion extends in a direction intersecting with both the first direction and the second direction;
the first curved portion is connected between the first straight portion and the fifth straight portion, the second curved portion is connected between the fifth straight portion and the fourth straight portion, the third curved portion is connected between the fourth straight portion and the sixth straight portion, and the fourth curved portion is connected between the sixth straight portion and the third straight portion; and
an included angle between the first straight portion and the fifth straight portion is greater than 90 degrees, an included angle between the fifth straight portion and the fourth straight portion is greater than 90 degrees, an included angle between the fourth straight portion and the sixth straight portion is greater than 90 degrees, and an included angle between the sixth straight portion and the third straight portion is greater than 90 degrees.

12. The display panel according to claim 1, wherein a minimum width of the pixel defining layer between adjacent pixel openings ranges from 6 μm to 20 μm in a direction parallel to a plane where the substrate is located.

13. A display panel, comprising:
a substrate;
an array circuit layer located on a side of the substrate and comprising a plurality of pixel drive units and a plurality of via holes, the plurality of pixel drive units comprising a plurality of first pixel drive units, and the plurality of via holes comprising a plurality of first via holes;
a pixel defining layer located on a side of the array circuit layer having the plurality of via holes, the pixel defining layer comprising a plurality of pixel openings, the plurality of pixel openings comprising a plurality of first pixel openings, an edge of the first pixel opening comprising a first straight portion, a second straight portion and a recessed portion, the first straight portion and the second straight portion being parallel and extending in a first direction, the recessed portion being connected to the first straight portion and extending in a second direction away from an extension line of the first straight portion and toward the second straight portion, and the first direction intersecting with the second direction;
an isolation structure enclosing a plurality of isolation openings, the plurality of isolation openings comprising a plurality of first isolation openings, the first isolation opening being in communication with a corresponding one of the plurality of first pixel openings; and
a plurality of light-emitting devices comprising a plurality of first light-emitting devices, the first light-emitting device being at least partially located in a corresponding one of the plurality of first isolation openings and connected to a corresponding one of the plurality of first pixel drive units through a corresponding one of the plurality of first via holes,
wherein the first via hole has a first orthographic projection on the substrate, a straight line where an orthographic projection of the first straight portion on the substrate lies is a first extension line, the recessed portion has a second orthographic projection on the substrate, and an area of the first orthographic projection on a side of the first extension line close to the second orthographic projection is less than an area of the first orthographic projection on a side of the first extension line away from the second orthographic projection.

14. The display panel according to claim 13, wherein the first extension line is located outside the first orthographic projection, or the first extension line passes through the first orthographic projection.

15. The display panel according to claim 13, wherein the plurality of light-emitting devices further comprises a plurality of second light-emitting devices and a plurality of third light-emitting devices, and the display panel comprises a plurality of pixels arranged in an array, the pixel comprising the first light-emitting device, the second light-emitting device and the third light-emitting device, wherein
in the same pixel, the first light-emitting device and the second light-emitting device are arranged in the second direction, the first light-emitting device and the third light-emitting device are arranged in the second direction, the second light-emitting device and the third light-emitting device are arranged in the first direction, and the second light-emitting device and the third light-emitting device are located on the same side of the first light-emitting device.

16. The display panel according to claim 15, wherein the plurality of pixel drive units further comprises a plurality of second pixel drive units and a plurality of third pixel drive units, and the plurality of via holes further comprise a plurality of second via holes and a plurality of third via holes, wherein
the first light-emitting device comprises a first lower electrode, a partial structure of the first lower electrode extending to the corresponding first via hole and being connected to the corresponding first pixel drive unit, the second light-emitting device comprises a second lower electrode, a partial structure of the second lower electrode extending to a corresponding one of the plurality of second via holes and being connected to a corresponding one of the plurality of second pixel drive units, and the third light-emitting device comprises a third lower electrode, a partial structure of the third lower electrode extending to a corresponding one of the plurality of third via holes and being connected to a corresponding one of the plurality of third pixel drive units; and
part of the first lower electrode is located between the second lower electrode and the third lower electrode.

17. The display panel according to claim 16, wherein the plurality of pixels comprise first pixels and second pixels adjacent to each other, part of the first lower electrode of the first pixel being located between the second lower electrode and the third lower electrode of the second pixel;
the first light-emitting device is a blue light-emitting device, one of the second light-emitting device and the third light-emitting device is a red light-emitting device, and the other of the second light-emitting device and the third light-emitting device is a green light-emitting device; and
the first light-emitting device comprises a first upper electrode on a side of the first lower electrode away from the substrate, the second light-emitting device comprises a second upper electrode on a side of the second lower electrode away from the substrate, and the third light-emitting device comprises a third upper electrode on a side of the third lower electrode away from the substrate, wherein the first upper electrode, the second upper electrode and the third upper electrode are in contact with the isolation structure.

18. The display panel according to claim 13, wherein the edge of the first pixel opening further comprises a third straight portion, the recessed portion being connected between the first straight portion and the third straight portion, wherein
a straight line where the third straight portion lies is located between a straight line where the first straight portion lies and a straight line where the second straight portion lies, or the straight line where the third straight portion lies and the straight line where the first straight portion lies are the same straight line.

19. The display panel according to claim 18, wherein the recessed portion comprises a fourth straight portion, a fifth straight portion, a sixth straight portion, a first curved portion, a second curved portion, a third curved portion and a fourth curved portion, wherein
the fourth straight portion is close to the second straight portion and extends in the first direction, the fifth straight portion extends in a direction intersecting with both the first direction and the second direction, and the sixth straight portion extends in a direction intersecting with both the first direction and the second direction;
the first curved portion is connected between the first straight portion and the fifth straight portion, the second curved portion is connected between the fifth straight portion and the fourth straight portion, the third curved portion is connected between the fourth straight portion and the sixth straight portion, and the fourth curved portion is connected between the sixth straight portion and the third straight portion; and
an included angle between the first straight portion and the fifth straight portion is greater than 90 degrees, an included angle between the fifth straight portion and the fourth straight portion is greater than 90 degrees, an included angle between the fourth straight portion and the sixth straight portion is greater than 90 degrees, and an included angle between the sixth straight portion and the third straight portion is greater than 90 degrees.

20. A display device, comprising a display panel of claim 1.
